(19) United States
(12) Patent Application Publication
(10) Pub. No.: US 2017/0248135 A1
(43) Pub. Date: Aug. 31, 2017

(54) AIR-COOLING SYSTEM AND AIRFLOW GENERATOR

(71) Applicant: GE AVIATION SYSTEMS LLC, Grand Rapids, MI (US)

(72) Inventors: Michael James DUSSEAU, Walker, MI (US); Stephen Nils HOLEN, Rockford, MI (US)

(21) Appl. No.: 15/507,081

(22) PCT Filed: Aug. 28, 2014
(86) PCT No.: PCT/US2014/053078

§ 371 Date: Feb. 27, 2017

(51) Int. Cl. F04B 45/047; H05K 7/20; F04B 53/08

(52) U.S. Cl. CPC F04B 45/047; F04B 53/08; H05K 7/20172; H05K 7/20436

(57) ABSTRACT

An air-cooling system (10, 110, 210) utilizing a synthetic jet or airflow generator (20, 120, 220) and airflow generators utilizing piezoelectrics (26, 126, 226) to cool heat-emitting elements (12, 112, 212). Actuation of the piezoelectrics (26, 126, 226) results in movement of one or more flexible structures (22, 24, 122, 124, 221) to increase the volume of one or more cavities (28, 30, 32, 128, 228, 230, 232) to draw air in and then decrease the volume of the one or more cavities (28, 30, 32, 128, 228, 230, 232) to push out the drawn in air.

### BACKGROUND OF THE INVENTION

Contemporary high-power-dissipating electronics produce heat that requires thermal management to maintain the electronics at a designed working temperature range. Heat must be removed from the electronic device to improve reliability and prevent premature failure of the electronics. Cooling techniques may be used to minimize hot spots.

### BRIEF DESCRIPTION OF THE INVENTION

In one aspect, an embodiment of the invention relates to an air-cooling system having a heat-emitting element having at least one of an interior or an exterior, a piezoelectric synthetic jet having opposed and spaced flexible plates defining a cavity there between wherein the piezoelectric synthetic jet is located either within the interior of the heat-emitting element, where the flexible plates are located within the interior, or about the exterior of the heat-emitting element, where at least a portion of the heat-emitting element extends into the cavity.

In another aspect, an embodiment of the invention relates to an airflow generator for use with an object having at least a first surface and a second surface, having a flexible structure having a first side where a first portion of the first side of the first flexible structure is spaced from a portion of the first surface of the object to define a first cavity there between and a second portion of the first side of the first flexible structure is spaced from a portion of the second surface of the object to define a second cavity there between, at least one piezoelectric located on the flexible structure wherein actuation of the at least one piezoelectric results in movement of the flexible structure to increase the volume of at least one of the first cavity or the second cavity to draw air in and then decrease the volume of the first cavity or the second cavity to push out the drawn in air such that the object is cooled by the airflow created by the airflow generator.

In yet another aspect, an embodiment of the invention relates to an airflow generator for cooling an object having at least a first surface and a second surface, having a first flexible structure having a first surface spaced from a portion of the first surface of the object to define a first cavity, a second flexible structure having a first surface spaced from a portion of the second surface of the object to define a second cavity and a piezoelectric located on each of the first flexible structure and the second flexible structure wherein actuation of the piezoelectrics results in movement of the first flexible structure and the second flexible structure to increase the volume of the first and second cavities to draw air in and then decrease the volume of the first and second cavities to push out the drawn in air.

### BRIEF DESCRIPTION OF THE DRAWINGS

In the drawings:

FIGS. 1A-1C are a schematic views of an air-cooling system according to a first embodiment;

FIGS. 2A-2C are schematic views of an alternative air-cooling system according to a second embodiment;

FIG. 3 is a perspective view of an air-cooling system having an alternative airflow generator according to another embodiment of the invention;

FIG. 4A is a side view of a flexible structure of the airflow generator of FIG. 3;

FIG. 4B is a top view of the air-cooling system of FIG. 3; and

FIGS. 5A and 5B are schematic views illustrating the operation of the airflow generator of FIG. 3.

### DESCRIPTION OF EMBODIMENTS OF THE INVENTION

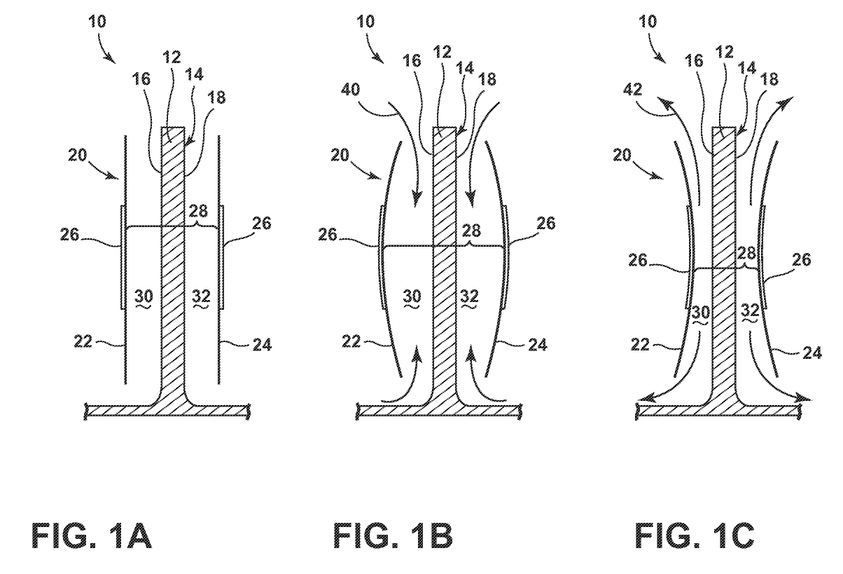

FIG. 1A illustrates an air-cooling system 10 having a heat-emitting element 12 having an exterior 14 that defines a first surface 16 and a second surface 18. The heat-emitting element 12 may include a heat-generating element or a heat-exchanging element. In the illustrated example, the heat-emitting element 12 has been illustrated as a heat-exchanging element in the form of a fin of a heat sink. While the heat-emitting element 12 has been illustrated as a fin having an exterior 14, it will be understood that the air-cooling system 10 may incorporate any suitable heat-emitting element having an exterior.

An airflow generator 20, which is illustrated as a piezoelectric synthetic jet, or is also included in the air-cooling system 10 and includes opposed and spaced flexible structures 22, 24 defining a cavity 28 there between. In the illustrated example the flexible structures 22, 24 have been illustrated as flexible plates 22, 24. The flexible structures 22, 24 may be formed from any suitable flexible material including aluminum, copper, stainless steel, etc. The flexible structures 22, 24 are spaced apart from each other and disposed in a generally confronting relationship along their major planes. The airflow generator 20 is illustrated as being located about the exterior 14 of the heat-emitting element 12 such that at least a portion of the heat-emitting element 12 extends into the cavity 28. More specifically the first flexible structure 22 is spaced from a portion of the first surface 16 of the heat-emitting element 12 to define a first cavity 30 and the second flexible structure 24 is spaced from a portion of the second surface 18 of the heat-emitting element 12 to define a second cavity 32.

A piezoelectric 26, for example a piezoelectric crystal, may be located on each of the flexible structures 22, 24. In the illustrated example, the piezoelectrics 26 are located at the center of each of the flexible structures 22, 24 although this need not be the case. While the piezoelectric 26 may be located, elsewhere locating each at the center of its respective flexible structure is believed to increase the deflection of the flexible structure. The piezoelectrics 26 may be operably coupled to suitable power sources through connections (not shown). Further, while only a single piezoelectric 26 has been illustrated on each flexible structure it will be understood that multiple piezoelectrics may be located on one or both of the flexible structures.

During operation, the actuation of the piezoelectrics 26 results in movement of the flexible structures 22, 24 to increase the volume of the cavity 28 to draw air in and then decrease the volume of the cavity 28 to push out the drawn in air. More specifically, when a voltage is applied to the piezoelectrics 26 the flexible structures 22, 24 are caused to bend such that they are convex as illustrated in FIG. 1B. As illustrated, the flexible structures 22, 24 deflect in opposite directions to each other. This simultaneous deflection increases the volume of the first cavity 30 and the second cavity 32 causing decreased partial pressure, which in turn causes air to enter the cavity 28 as illustrated by the arrows 40. When a voltage of opposite polarity is applied, the flexible structures 22, 24 bend in the opposite direction (i.e. concave instead of convex) as illustrated in FIG. 1C. This action decreases the volume of the cavity 28 and causes air to be expelled as illustrated by the arrows 42. While it is preferred that the flexible structures 22, 24 go past the neutral position (FIG. 1A) to expel a larger volume of air, it will be understood that any movement of the flexible structures 22, 24 back toward the neutral position would push out some air. The piezoelectrics 26 are connected to a controllable electric source (not shown) so that an alternating voltage of the desired magnitude and frequency may be applied to the piezoelectrics 26. The motion of the flexible structures 22, 24 creates a flow of air that may be utilized in cooling heat-emitting elements.

In the above-described example, both the first cavity 30 and the second cavity 32 draw air in and push out the drawn in air simultaneously. Because the heat-emitting element 12 is within the cavity 28 and separates the cavity 28 it is also contemplated that the flexible structures 22, 24 may be actuated such that they do not move in opposing directions and that only a single flexible structure needs to be moved convexly to increase the volume of the cavity 28. By way of further non-limiting example, actuation of the piezoelectric 26 on the flexible structure 22 may result in movement of the flexible structure 22 to increase the volume of the first cavity 30 while at the same time the actuation of the piezoelectric 26 on the flexible structure 24 may result in movement of the flexible structure 24 to decrease the volume of the second cavity 32. Then, the flexible structures 22, 24 may be moved in opposite directions such that the volume of the first cavity 30 is decreased and the volume of the second cavity 32 is increased. The actuation of the piezoelectrics 26 for the flexible structures 22, 24 may also not be simultaneous. Such alternative operations may still provide for the creation of airflows that cool the heat-emitting element 12.

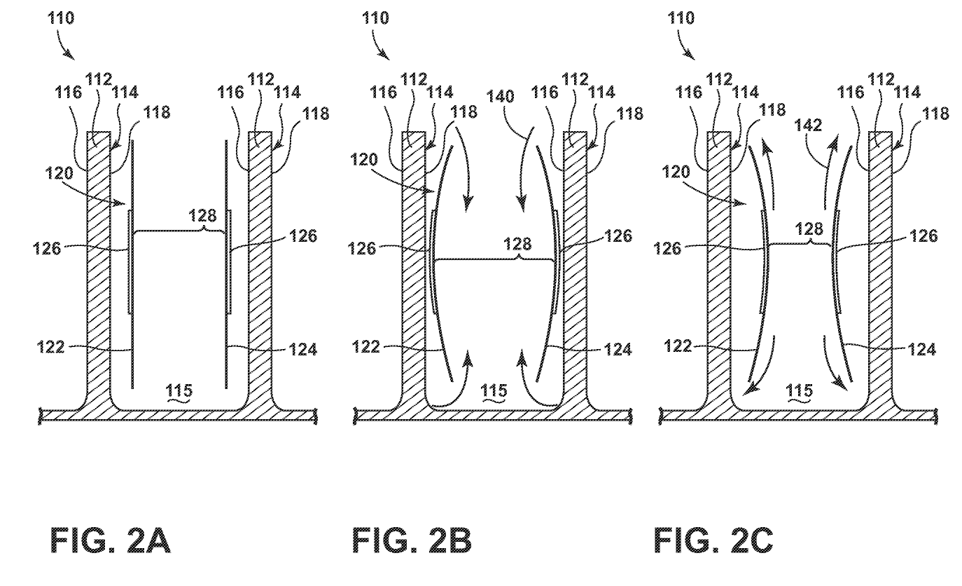

By way of further non-limiting example, FIGS. 2A-2C illustrate an alternative air-cooling system 110 according to a second embodiment of the invention. The air-cooling system 110 is similar to the air-cooling system 10 previously described and therefore, like parts will be identified with like numerals increased by 100, with it being understood that the description of the like parts of the air-cooling system 10 applies to the air-cooling system 110, unless otherwise noted.

One difference is that the air-cooling system 110 includes a heat-emitting element 112 having an interior 115. While the heat-emitting element 112 has been illustrated as including two fins that define an interior 115 it will be understood that the air-cooling system 110 may incorporate any suitable heat-emitting element 112 having an interior 115. Another difference is that the airflow generator 120 while having opposed and spaced flexible structures 122, 124 and defining a cavity 128 there between is instead located within the interior 115 of the heat-emitting element 112. The operation of the airflow generator 120 is similar to that of the airflow generator previously described such that actuation of the piezoelectrics results in movement of the flexible structures 122, 124 to increase the volume of the cavity 128 to draw air in and then decrease the volume of the cavity 128 to push out the drawn in air.

In the above embodiments, the airflow generator may be mounted around or within the heat-emitting element in any suitable manner. By way of non-limiting example, multiple brackets may be used for mounting one or both of the flexible structures to the heat-emitting element or a structure near the heat-emitting element.

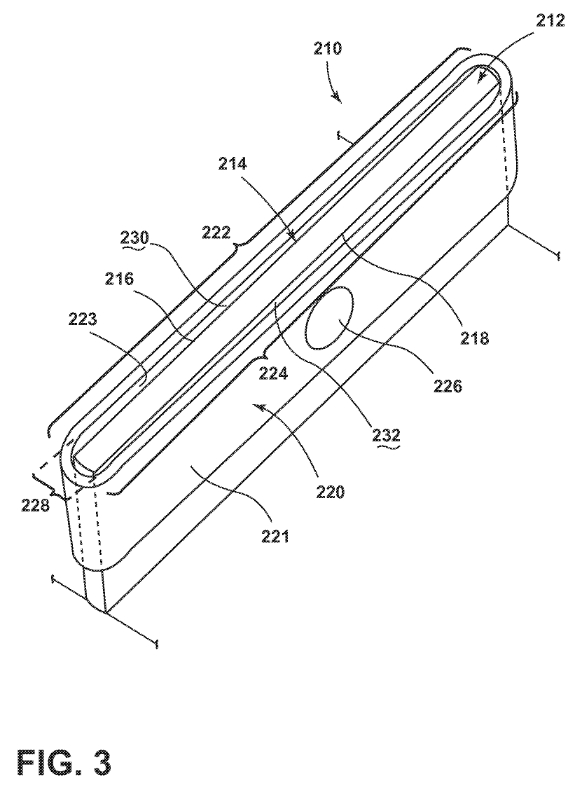

By way of further non-limiting example, FIG. 3 illustrates an alternative air-cooling system 210 according to a third embodiment of the invention. The air-cooling system 210 is similar to the air-cooling system 10 previously described and therefore, like parts will be identified with like numerals increased by 200, with it being understood that the description of the like parts of the air-cooling system 10 applies to the air-cooling system 210, unless otherwise noted.

One difference is that the airflow generator 220 includes a single flexible structure 221. In the illustrated example, the flexible structure 221 is illustrated as being wrapped around heat-emitting element 212 such that it encircles the heat-emitting element 212, although this need not be the case. The flexible structure 221 includes a first side 223 with a first portion 222 and a second portion 224. The first portion 222 of the flexible structure 221 is spaced from a portion of a first surface 216 of the heat-emitting element 212 to define a first cavity 230 there between. The second portion 224 of the flexible structure 221 is spaced from a portion of a second surface 218 of the heat-emitting element 212 to define a second cavity 232 there between. The single flexible structure 221 may be thought of as two flexible plates that are operably coupled and surround at least a portion of the heat-emitting element 212; however, such flexible plates are integrally formed to form the single flexible structure 221.

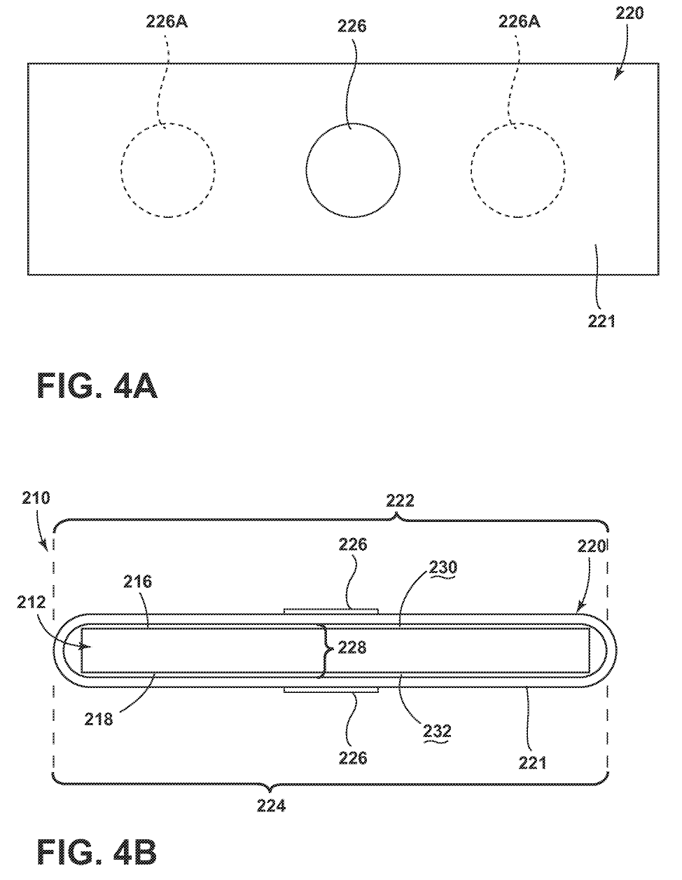

At least one piezoelectric 226 may be located on the flexible structure 221 of the airflow generator 220. Further, multiple piezoelectrics 226 may be located on the flexible structure 221. In the illustrated example of FIG. 3, two piezoelectrics 226 are located on the flexible structure 221. In FIG. 4A, two additional piezoelectrics 226 are illustrated as being included on one of the portions of the flexible structure 221 to aid in illustrating how multiple piezoelectrics 226 may be included. It will be understood that any number of piezoelectrics 226 may be included on the flexible structure 221 including a single piezoelectric. If multiple piezoelectrics 226 are included, they may be configured to be actuated simultaneously. Returning to the exemplary embodiment, a top view of which is shown in FIG. 4B, one of the piezoelectrics 226 is located adjacent the first cavity 230 and another piezoelectric 226 is located adjacent the second cavity 232.

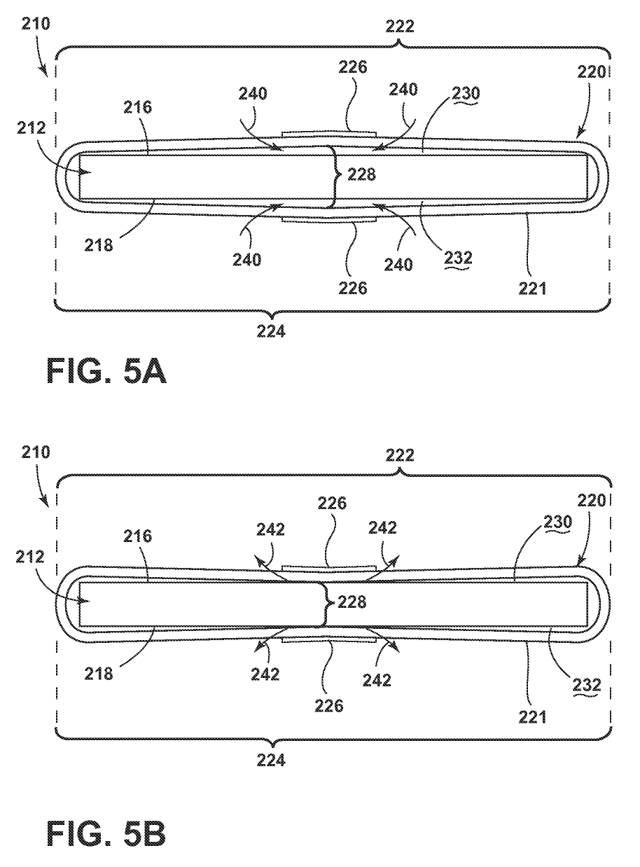

FIGS. 5A and 5B are schematic views illustrating an exemplary operation of the airflow generator 220. During such operation, the actuation of the multiple piezoelectrics 226 results in movement of the flexible structure 221 to increase the volume of both the first cavity 230 and the second cavity 232 to draw air in to the cavities 230, 232 and then decrease the volume of the first cavity 230 and the second cavity 232 to push out the drawn in air such that the heat-emitting element 212 is cooled by the airflow created by the airflow generator 220. It is contemplated that the multiple piezoelectrics 226 may not be actuated simultaneously or that the cavities 230, 232 may be enlarged and decreased at different times.

It will be understood that the airflow generators described above may be oriented in any suitable manner with respect to the heat-emitting element such that the airflow generator may produce a flow of air that aids in cooling the heat-emitting element. The airflow generators may be utilized with any device that requires thermal management for heat dissipation such as electronic components that require a uniform temperature distribution due to thermal sensitivity. For example, the airflow generators may be used with both airborne, shipboard, and ground based electronics.

The embodiments described above provide a variety of benefits including that such airflow generators solve the thermal management problem of cooling electronic devices with high power dissipations, with local hot spots, or electronic components that require a uniform temperature distribution. The airflow generators described above are easy to manufacture, have low electrical draw, are lightweight, and increase component reliability. The above-described embodiments capture a greater volume of air between the plates than an airflow generator without such recesses. The greater volumetric air trapped between the plates result in a greater exiting volumetric airflow from the airflow generator.

To the extent not already described, the different features and structures of the various embodiments may be used in combination with each other as desired. Some features may not be illustrated in all of the embodiments, but may be implemented if desired. Thus, the various features of the different embodiments may be mixed and matched as desired to form new embodiments, whether or not the new embodiments are expressly described. All combinations or permutations of features described herein are covered by this disclosure.

This written description uses examples to disclose the invention, including the best implementation, to enable any person skilled in the art to practice the invention, including making and using the devices or systems described and performing any incorporated methods presented. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An air-cooling system comprising:
a heat-emitting element having at least one of an interior or an exterior; and
a piezoelectric air generator having opposed and spaced flexible plates defining a cavity there between;
wherein the piezoelectric synthetic jet is located either within the interior of the heat-emitting element, where the flexible plates are located within the interior, or about the exterior of the heat-emitting element, where at least a portion of the heat-emitting element extends into the cavity.

2. The air-cooling system of claim 1 wherein the heat-emitting element further comprises a heat-generating element or a heat-exchanging element.

3. The air-cooling system of claim 2 wherein the heat-exchanging element comprises a fin of a heat sink.

4. The air-cooling system of claim 3 wherein the flexible plates of the piezoelectric air generator are operably coupled and surround at least a portion of the fin.

5. The air-cooling system of claim 4 wherein the flexible plates are integrally formed.

6. The air-cooling system of claim 1 wherein multiple piezoelectrics are located on at least one of the flexible plates.

7. An airflow generator for use with an object having at least a first surface and a second surface, comprising:
a flexible structure having a first side where a first portion of the first side of the flexible structure is spaced from a portion of the first surface of the object to define a first cavity there between and a second portion of the first side of the flexible structure is spaced from a portion of the second surface of the object to define a second cavity there between; and
at least one piezoelectric located on the flexible structure;
wherein actuation of the at least one piezoelectric results in movement of the flexible structure to increase the volume of at least one of the first cavity or the second cavity to draw air in and then decrease the volume of the first cavity or the second cavity to push out the drawn in air such that the object is cooled by the airflow created by the airflow generator.

8. The airflow generator of claim 7 wherein multiple piezoelectrics are located on the flexible structure.

9. The airflow generator of claim 8 wherein at least one of the multiple piezoelectrics is located adjacent the first cavity and at least another of the multiple piezoelectrics is located adjacent the second cavity.

10. The airflow generator of claim 8 wherein actuation of the multiple piezoelectrics results in movement of the flexible structure to increase the volume of both the first cavity and the second cavity to draw air in and then decrease the volume of the first cavity and the second cavity to push out the drawn in air such that the object is cooled by the airflow created by the airflow generator.

11. The airflow generator of claim 8 wherein the multiple piezoelectrics are configured to be actuated simultaneously.

12. The airflow generator of claim 7 wherein the flexible structure encircles at least a portion of the object.

13. An airflow generator for cooling an object having at least a first surface and a second surface, comprising:
a first flexible structure having a first surface spaced from a portion of the first surface of the object to define a first cavity;
a second flexible structure having a first surface spaced from a portion of the second surface of the object to define a second cavity; and
a piezoelectric located on each of the first flexible structure and the second flexible structure;
wherein actuation of the piezoelectrics results in movement of the first flexible structure and the second flexible structure to increase the volume of the first and second cavities to draw air in and then decrease the volume of the first and second cavities to push out the drawn in air.

14. The airflow generator of claim 13 wherein multiple piezoelectrics are located on at least one of the first flexible structure or the second flexible structure.

15. The airflow generator of claim 14 wherein the multiple piezoelectrics are configured to be actuated simultaneously.

16. The airflow generator of claim 13 wherein at least one of the first flexible structure or the second flexible structure is a plate.

17. The airflow generator of claim 13, further comprising multiple brackets for mounting at least one of the first flexible structure or the second flexible structure to the object.

18. The airflow generator of claim 13 wherein the piezoelectric is located at the center of first flexible structure.
